(19) United States
(12) Patent Application Publication
(10) Pub. No.: US 2025/0080051 A1
(43) Pub. Date: Mar. 6, 2025

(54) POWER SUPPLY SYSTEM

(71) Applicant: Murata Manufacturing Co., Ltd., Kyoto (JP)

(72) Inventor: Shun IMAI, Kyoto (JP)

(21) Appl. No.: 18/823,880

(22) Filed: Sep. 4, 2024

(30) Foreign Application Priority Data
Sep. 6, 2023 (JP) 2023-144565

(51) Int. Cl. H03F 1/02; H03F 3/24

(52) U.S. Cl. CPC H03F 1/0211; H03F 3/245; H03F 2200/451

(57) ABSTRACT

A power supply system includes: a first module including a first power amplifier; a first power line supplying power to the first module; a second power line supplying power to the first module; a first capacitance connected at one end to the first power line; a second capacitance connected at one end to the second power line; a first switch that switches between a state in which the first power line is electrically connected to the first module and a state in which the second power line is electrically connected to the first module; a second switch that can connect the second capacitance to a reference potential when the first power line is connected to the first module; and a third switch that can connect the first capacitance to a reference potential when the second power line is connected to the first module.

### CROSS REFERENCE TO RELATED APPLICATION

This application claims priority from Japanese Patent Application No. 2023-144565 filed on Sep. 6, 2023. The content of this application is incorporated herein by reference in its entirety.

### BACKGROUND ART

The present disclosure relates to a power supply system.

Some wireless communication devices have a plurality of power amplifier (hereinafter referred to as “PA”) modules to deal with multiple frequency bands. When a plurality of power amplifiers are provided in a communication device, it is necessary to provide power modulators to supply power to the power amplifiers.

U.S. Patent Application Publication No. 2007/0010218 discloses a wireless communication device having a plurality of power supply circuits, in particular a power supply circuit which supplies a low power supply voltage when the power is low, and a power supply circuit which quickly supplies a high power supply voltage when the power is high. The power supply circuits are switched as necessary.

### BRIEF SUMMARY

Regarding power supply circuits for PA modules, it is conceivable to provide the same number of power supply circuits as that of the PA modules so that there is a one-to-one relationship between the PA modules and the power supply circuits. In that case, the provision of the same number of power supply circuits for multiple PA modules makes it difficult to provide a small-sized device. It is, therefore, conceivable to provide a selector switch and supply power from one power supply circuit to a plurality of PA modules, thus reducing the number of power supply devices.

However, when multiple types of PA modules with different frequency bands are provided, a leakage current may leak to a power line via a selector switch. Such a leakage current affects the PA modules.

The present disclosure provides a power supply system which, when a power supply circuit and a selector switch are used, can reduce the influence of a leakage current from a PA module.

The present disclosure provides a power supply system comprising: a first module including a first power amplifier for amplifying a signal; a first power line for supplying power to the first module; a second power line for supplying power to the first module; a first capacitor connected at one end to the first power line; a second capacitor connected at one end to the second power line; a first switch which switches between a first connection state in which the first power line is electrically connected to the first module and a second connection state in which the second power line is electrically connected to the first module; a second switch which, when the first power line is connected to the first module by the first switch and the first module is driven, can connect the other end of the second capacitor to a reference potential; and a third switch which, when the second power line is connected to the first module by the first switch and the first module is driven, can connect the other end of the first capacitor to a reference potential.

According to the present disclosure, when a power supply circuit and a selector switch are used, the influence of a leakage current from a PA module can be reduced.

### BRIEF DESCRIPTION OF THE DRAWINGS

FIG. 1 is a block diagram showing a power supply system according to a first embodiment of the present disclosure;

FIG. 2 is a diagram showing the operating states of PA modules and the corresponding states of switches;

FIG. 3 is a block diagram showing a power supply system according to a second embodiment of the present disclosure;

FIG. 4 is a diagram showing the operating states of PA modules in response to switching of a switch and the corresponding states of other switches;

FIG. 5 is a diagram illustrating band combinations which cause deterioration of intermodulation distortion characteristics;

FIG. 6 is a diagram illustrating isolation characteristics between two power lines.

FIG. 7 is a diagram showing the operating states of PA modules in the state shown in FIG. 6, and the corresponding states of switches;

FIG. 8 is a diagram showing an example of a leakage signal in FIG. 6;

FIG. 9 is a diagram showing an example of a power supply system which uses three power modulators for four PA modules;

FIG. 10 is a diagram illustrating whether the power modulators can deal with the EN-DC combinations shown in FIG. 9;

FIG. 11 is a diagram showing an example of a power supply system which uses two power modulators for four PA modules;

FIG. 12 is a diagram illustrating whether the power modulators can deal with the EN-DC combinations shown in FIG. 11;

FIG. 13 is a diagram showing another example of a power supply system which uses two power modulators for four PA modules;

FIG. 14 is a diagram illustrating whether the power modulators can deal with the EN-DC combinations shown in FIG. 13; and

FIG. 15 is a block diagram showing a power supply system according to a third embodiment of the present disclosure.

### DETAILED DESCRIPTION

Embodiments of the present disclosure will now be described in detail based on the drawings. In the following description of each embodiment, components or elements which are the same as or equivalent to those of other embodiment(s) are given the same reference signs, and a description thereof will be simplified or omitted. The present disclosure is not limited to the embodiments. Any component or element in each embodiment will include those which are replaceable as is obvious to a person skilled in the art, or those which are substantially the same. The features described below can be arbitrarily combined with one another. Further, omissions, replacements, or modifications may be made to the embodiments without necessarily departing from the spirit and scope of the disclosure.

### First Embodiment

### Construction

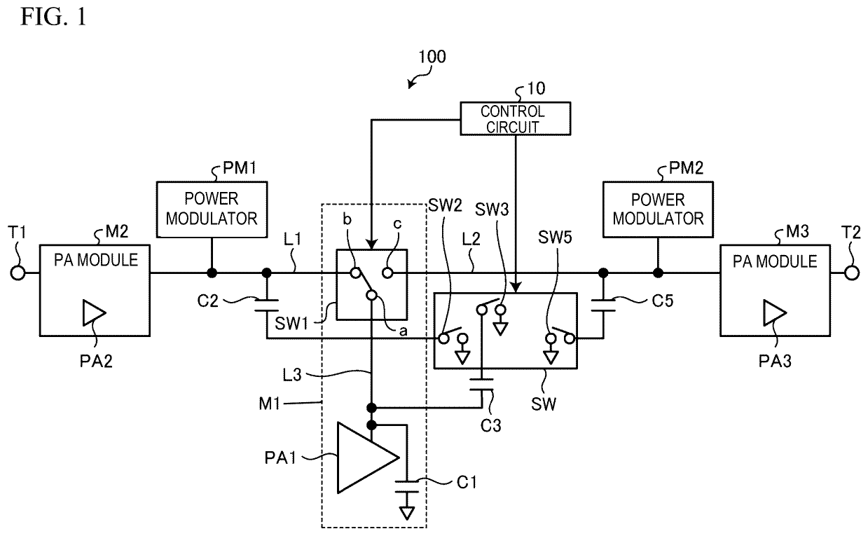

FIG. 1 is a block diagram showing a power supply system according to a first embodiment of the present disclosure. In FIG. 1, the power supply system 100 according to the first embodiment includes PA modules M1, M2, M3, power modulators PM1, PM2, a switch circuit SW, capacitors C1, C2, C3, C5, power lines L1, L2, L3, a control circuit 10, and terminals T1, T2. FIG. 1 mainly shows the state of connection of the power lines for supplying the power of the power supply system 100.

The PA module M1 includes a power amplifier PA1, a switch SW1, and a power line L3. The power amplifier PA1 amplifies a high-frequency signal. The power line L3 is connected to the PA module M1. The power line L3 electrically connects the switch SW1 and the PA module M1. The PA module M1 corresponds to the “first module” of the present disclosure. The power line L3 corresponds to the “third power line” of the present disclosure.

The PA module M2 includes a power amplifier PA2. The PA module M2 corresponds to the “second module” of the present disclosure, and the power amplifier PA2 corresponds to the “second power amplifier” of the present disclosure. The power amplifier PA2 amplifies a high-frequency signal. The PA module M2 is connected to the power line L1 without necessarily via the switch SW1, and is located on the opposite side of the below-described capacitor C2 from the PA module M1. The PA module M3 includes a power amplifier PA3. The PA module M3 corresponds to the “third module” of the present disclosure, and the power amplifier PA3 corresponds to the “third power amplifier” of the present disclosure. The Power amplifier PA3 amplifies a high-frequency signal. The PA module M3 is connected to the power line L2 without necessarily via the switch SW1, and is located on the opposite side of the below-described capacitor C5 from the PA module M1.

The power modulators PM1, PM2 output a power supply voltage. The PA module M2 and the power modulator PM1 are connected to the power line L1. The power modulator PM1 supplies a power supply voltage to the power line L1. The PA module M3 and the power modulator PM2 are connected to the power line L2. The power modulator PM2 supplies a power supply voltage to the power line L2. The power line L1 corresponds to the “first power line” of the present disclosure. The power line L2 corresponds to the “second power line” of the present disclosure.

The switch SW1 is provided in the PA module M1. The switch SW1 is a switch for switching between the power modulators. The switch SW1 has contacts a, b, and c. A control signal, outputted by the control circuit 10, is inputted to the switch SW1. Based on the inputted control signal, the switch SW1 enters a state in which the contact a and the contact b are connected, or a state in which the contact a and the contact c are connected. The power line L3 is connected to the contact a. The power line L1 is connected to the contact b. The power line L2 is connected to the contact c. The switch SW1 can enter an open state with none of the contacts connected.

When the switch SW1 connects the contact a and the contact b, it electrically connects the power line L1 and the power line L3. When the switch SW1 connects the contact a and the contact c, it electrically connects the power line L2 and the power line L3. Thus, based on an input control signal, the switch SW1 switches between the two connection states. In particular, the switch SW1 switches between a first connection state, in which the power line L1 is electrically connected to the PA module M1, and a second connection state in which the power line L2 is electrically connected to the PA module M1.

The switch circuit SW is an integrated circuit including switches SW2, SW3, SW5. Thus, the switches SW2, SW3, SW5 are provided in the same integrated circuit. A control signal, outputted by the control circuit 10, is inputted to the switch circuit SW. The switches SW2, SW3, SW5 are turned on or off based on the input control signal received from the control circuit 10. The switch SW2 is, for example, comprised of a transistor. The switch SW2 is turned on when the transistor is turned on, while the switch SW2 is turned off when the transistor is turned off. The switches SW3, SW5 each has the same construction as the switch SW2.

One end of the capacitor C1 is connected to the power line L3. The other end of the capacitor C1 is connected to a reference potential. The reference potential is, for example, a ground potential. The same holds true in the following description.

One end of the capacitor C2 is connected to the power line L1. In particular, the capacitor C2 is connected to the power line L1 at a position between the PA module M2 and the switch SW1. In other words, the capacitor C2 is connected to the power line L1 at a position between the PA module M1 and the PA module M2. The other end of the capacitor C2 is to be connected to a reference potential via the switch SW2. When the switch SW2 is on, the other end of the capacitor C2 is connected to the reference potential. When the power line L2 is connected to the PA module M1 by the switch SW1 and the PA module M1 is driven, the other end of the capacitor C2 is connected to the reference potential by the switch SW2. The capacitor C2 corresponds to the “first capacitor” of the present disclosure. The switch SW1 corresponds to the “first switch” of the present disclosure. The switch SW2 corresponds to the “third switch” of the present disclosure.

One end of the capacitor C5 is connected to the power line L2. The other end of the capacitor C5 is to be connected to a reference potential via the switch SW5. When the switch SW5 is on, the other end of the capacitor C5 is connected to the reference potential. When the power line L1 is connected to the PA module M1 by the switch SW1 and the PA module M1 is driven, the other end of the capacitor C5 is connected to the reference potential by the switch SW5. The capacitor C5 corresponds to the “second capacitor” of the present disclosure. The switch SW5 corresponds to the “second switch” of the present disclosure.

One end of the capacitor C3 is connected to the power line L3. The other end of the capacitor C3 is to be connected to a reference potential via the switch SW3. When the switch SW3 is on, the other end of the capacitor C3 is connected to the reference potential. Thus, the switch SW3 switches between a state in which the other end of the capacitor C3 is connected to the reference potential and a state in which the other end of the capacitor C3 is not connected to the reference potential. The capacitor C3 corresponds to the “third capacitor” of the present disclosure.

### Operation

The power supply system 100 operates on the condition that power is supplied from one power modulator to one PA module. This applies also after the state of connection is switched by the switch SW1. When switching the state of connection of the power modulators PM1, PM2 to the power lines L1, L2, the switches other than the switch SW1 are operated simultaneously with switching of the switch SW1, thereby setting connection or non-connection of each capacitor. Thus, the switches SW2 to SW5 are switched in conjunction with switching between the power supplies by the switch SW1 and with the drive state of the PA module M1. As used herein, the phrase “switched in conjunction with” includes, besides simultaneous switching, a case where the switching timings somewhat differ. In the case of non-simultaneous switching, the switches SW2 to SW5 can be first switched, and then switch the switch SW1 in order to reduce the influence of a leakage current. The operation of the power supply system 100 will now be described in greater detail.

The power modulator PM1 supplies a power supply voltage to the power line L1. Thus, the power modulator PM1 supplies power to the power line L1. The power modulator PM2 supplies a power supply voltage to the power line L2. Thus, the power modulator PM2 supplies power to the power line L2.

The PA module M1 is in a drive state when power supplied by the power line L3, i.e., a power supply voltage, has been inputted and a predetermined bias is applied. The PA module M1 in the drive state amplifies a high-frequency signal inputted to a not-shown terminal. The PA module M2 is in a drive state when power supplied by the power line L1, i.e., a power supply voltage, has been inputted and a predetermined bias is applied. The PA module M2 in the drive state amplifies a high-frequency signal inputted to the terminal T1. The PA module M3 is in a drive state when power supplied by the power line L2, i.e., a power supply voltage, has been inputted and a predetermined bias is applied. The PA module M3 in the drive state amplifies a high-frequency signal inputted to the terminal T2.

The PA modules M1, M2, M3 amplify signals in different frequency bands. The PA module M1 amplifies, for example, UHB (ultra-high band) signals (3.5 GHz band). The PA module M2 amplifies, for example, LB (low band) signals (0.9 GHz band). The PA module M3 amplifies, for example, MB (mid-band) signals (1.8 GHz band).

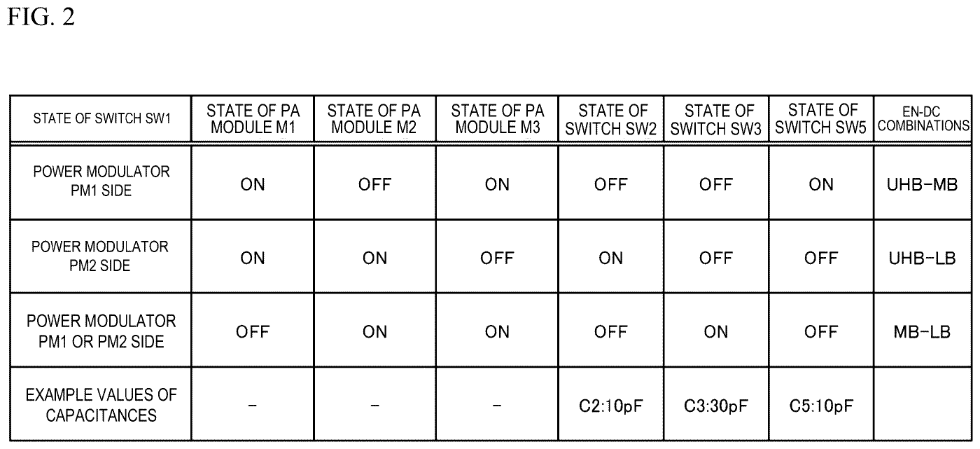

FIG. 2 is a diagram showing the operating states of the PA modules and the corresponding states of the switches. FIG. 2 shows the operating states of the PA modules in response to switching of the switch SW1 and the corresponding states of the other switches SW2, SW3, SW5. The “ON” (hereinafter referred to as “on”) state of each PA module in FIG. 2 indicates that the PA module is in a drive state and can amplify signals by a gain of more than 0. The “OFF” (hereinafter referred to as “off”) state of each PA module in FIG. 2 indicates that the PA module is not in a drive state. The “ON” (hereinafter referred to as “on”) state of each switch in FIG. 2 indicates that the switch is in a conductive state, while the “OFF” (hereinafter referred to as “off”) state of each switch indicates that the switch is not in a conductive state. FIG. 2 also shows feasible EN-DC (E-UTRA New Radio-Dual Connectivity) combinations. “E-UTRA” is an abbreviation for Evolved Universal Terrestrial Radio Access.

In FIG. 2, when the PA module M1 is on, the PA module M2 is off, and the PA module M3 is on with the contact a of the switch SW1 connected to the power modulator PM1-side contact b, the switches SW2 and SW3 are made off and the switch SW5 is made on. This can achieve a combination of UHB and MB.

By making the switches SW2 and SW3 off, the influences of the capacitors C2, C3 can be eliminated, thereby improving the responsiveness of the PA module M1. By making the switch SW5 on to activate the capacitor C5, the influence of a leakage signal, which is a signal in the frequency band in which the PA module M1 operates or its harmonic signal, leaking to the PA module M3 via the power lines L2 and L3, is reduced. At the same time, by making the switch SW5 on to activate the capacitor C5, the influence of a leakage signal, which is a signal in the frequency band in which the PA module M3 operates or its harmonic signal, leaking to the PA module M1 via the power lines L2 and L3, is reduced. This can ensure good isolation characteristics between the power lines L1, L3 and the power line L2.

If the capacitor C2 is connected between the power line L1 and the reference voltage, or the capacitor C3 is connected between the power line L3 and the reference voltage, the capacitance will affect and deteriorate the initial response performance in the operation of the PA module M1. In other words, if the capacitors C2 and C3, connected to the power lines L1, L3 connecting the PA module M2 in the off state, which shares the power line L1 with the PA module M1 in the on state, and the PA module M1, are connected to the reference voltage, the initial response performance in the operation of the PA module M1 will deteriorate. The deterioration of the initial response performance in the operation of the PA module M1 can be prevented by making the switches SW2, SW3, SW4 off as described above, thereby eliminating the influences of the capacitors C2, C3, C4.

In FIG. 2, when the PA module M1 is on, the PA module M2 is on, and the PA module M3 is off with the contact a of the switch SW1 connected to the power modulator PM2-side contact c, the switch SW2 is made on and the switches SW3 and SW5 are made off. This can achieve a combination of UHB and LB.

By making the switches SW3 and SW5 off, the influences of the capacitors C3, C5 can be eliminated, thereby improving the responsiveness of the PA module M1. By making the switch SW2 on to activate the capacitor C2, the influence of a leakage signal, which is a signal in the frequency band in which the PA module M1 operates or its harmonic signal, leaking to the PA module M2 via the power lines L1 and L3, is reduced. At the same time, by making the switch SW2 on to activate the capacitor C2, the influence of a leakage signal, which is a signal in the frequency band in which the PA module M2 operates or its harmonic signal, leaking to the PA module M1 via the power lines L1 and L3, is reduced. This can ensure good isolation characteristics between the power line L1 and the power lines L2, L3.

If the capacitor C5 is connected between the power line L2 and the reference voltage, or the capacitors C3, C4 are connected between the power line L3 and the reference voltage, the capacitance will affect and deteriorate the initial response performance in the operation of the PA module M1. In other words, if the capacitors C3 and C5, connected to the power lines L2, L3 connecting the PA module M3 in the off state, which shares the power line L2 with the PA module M1 in the on state, and the PA module M1, are connected to the reference voltage, the initial response performance in the operation of the PA module M1 will deteriorate. The deterioration of the initial response performance in the operation of the PA module M1 can be prevented by making the switches SW5, SW3, SW4 off as described above, thereby eliminating the influences of the capacitors C5, C3, C4.

In FIG. 2, regardless of the state of connection of the contacts a, b, and c of the switch SW1, i.e., both in the case where the contact a of the switch SW1 is connected to the contact b and in the case where the contact a of the switch SW1 is connected to the contact c, when the PA module M1 is off and the PA modules M2 and M3 are on, the switch SW2 is made off, the switch SW3 is made on, and the switch SW5 is made off. This can achieve a combination of MB and LB.

By making the switches SW2 and SW5 off, it is possible to eliminate the influences of the capacitors C2, C5 connected to the power lines L1, L2 shared by the PA modules M2, M3 in the on state and the PA module M1 in the off state, thereby improving the responsiveness of the PA modules M2 and M3. By making the switch SW3 on to activate the capacitor C3, the influence of a leakage signal, which is a signal in the frequency band in which the PA modules M2, M3 operate or its harmonic signal, leaking via the power lines L1 and L2, is reduced. This can ensure good isolation characteristics between the power line L1 and the power line L2.

When the switch SW1 is in an open state without necessarily any connection between the contacts, and when PA module M1 is off and the PA modules M2 and M3 are on, the switch SW2 or the switch SW5 is made on and the switch SW3 is made off. This can also achieve a combination of MB and LB.

By making the switch SW3 off, it is possible to eliminate the influence of the capacitor C3 connected to the power line L3 shared, via the switch SW1, by the PA modules M2, M3 in the on state and the PA module M1 in the off state, thereby improving the responsiveness of the PA modules M2 and M3. By making the switch SW2 or SW5 on to activate the capacitor C2 or the capacitor C5, the influence of a leakage signal, which is a signal in the frequency band in which the PA modules M2, M3 operate or its harmonic signal, leaking via the power lines L1 and L2, is reduced. This can ensure good isolation characteristics between the power line L1 and the power line L2.

FIG. 2 also shows example values of the capacitances. For example, the capacitance of the capacitor C2 is 10 pF, the capacitance of the capacitor C3 is 30 pF, and the capacitance of the capacitor C5 is 10 pF.

### Effect

As described above with reference to FIG. 2, a capacitor of an appropriate value can be connected to a power line depending on the operating state of each PA module. By connecting a reference potential to the other end of the capacitor, the influence of a leakage signal, leaking through a power line, can be reduced. This can achieve good isolation characteristics between power lines.

For a capacitor(s) which does not need to be connected, the switch is set to be off so as not to connect the capacitor(s) to the reference potential. This makes it possible to prevent deterioration of the initial response performance in the operation of a PA module.

In some cases, a capacitor is connected to a power line to remove noise on the power line or to determine the responsiveness of a power supply voltage. The capacitor connected to the power line is a fixed value regardless of the number of PA modules and the frequency band of signals used. Recent mobile communication terminals have a plurality of PA modules to support more frequency bands so as to enable high-speed, high-capacity communication. When power is supplied from a power modulator to a plurality of PA modules, if a plurality of PA modules for different frequency bands are connected to each power line, the use of a fixed capacitance value cannot achieve a good isolation performance to reduce power supply noise including harmonics.

According to the power supply system described above, the switches are made on or off in conjunction with switching between the power modulators that supply power to the PA module. This makes it possible to reduce the influence of a leakage signal leaking through a power line, thereby achieving good isolation characteristics between power lines. In addition, the power supply system can prevent deterioration of the initial response performance in the operation of a PA module. In particular, in conjunction with switching between the power modulator, the isolation characteristics of a power supply, the responsiveness upon switching between power supplies, and the high efficiency and high linearity characteristics adapted for the power supply method, such as APT or ET, can be optimized according to the frequency bands of PA modules used.

### Second Embodiment

### Construction

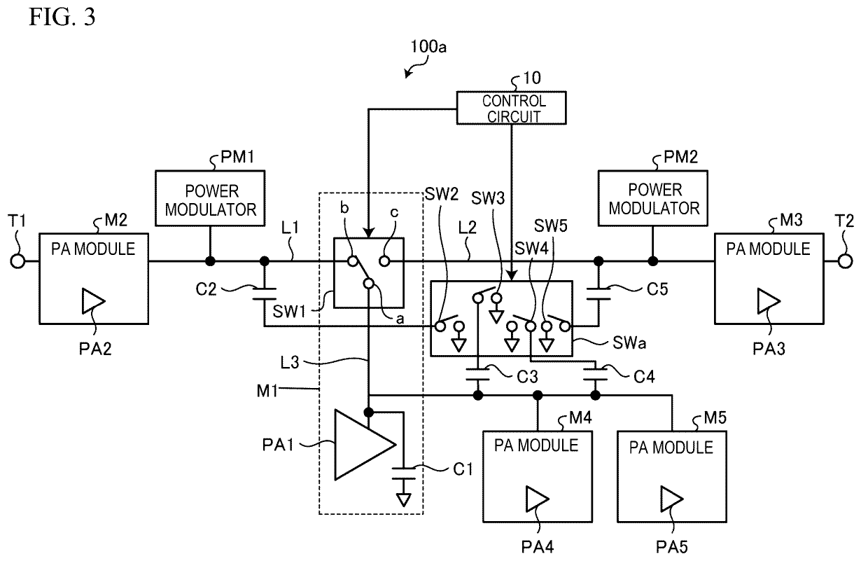

FIG. 3 is a block diagram showing a power supply system according to a second embodiment of the present disclosure. In FIG. 3, the power supply system 100a according to the second embodiment adds PA modules M4, M5 and capacitors C3, C4 to the power supply system 100 according to the first embodiment. The PA module M4 includes a power amplifier PA4. The power amplifier PA4 amplifies a high-frequency signal. The PA module M5 includes a power amplifier PA5. The power amplifier PA5 amplifies a high-frequency signal. The capacitor C3 is provided for the PA module M4. The capacitor C4 is provided for the PA module M5.

The PA module M4 operates on power supplied through the power line L3. The PA module M5 operates on power supplied through the power line L3. The frequency band of signals, to be amplified by the power amplifier PAL in the PA module M1, differs from the frequency band of signals to be amplified by the power amplifiers PA4, PA5 in the PA modules M4, M5. The PA modules M4, M5 correspond to the “fourth modules” of the present disclosure. The power amplifiers PA4, PA5 correspond to the “fourth power amplifiers” of the present disclosure.

In the first connection state described above, the power line L1 and the power line L3 are electrically connected. In the first connection state, power is supplied to one of the PA modules M1, M4, M5 via the power line L1 and the power line L3.

In the second connection state described above, the power line L2 and the power line L3 are electrically connected. In the second connection state, power is supplied to all of the PA modules M1, M4, M5 via the power line L2 and the power line L3. Each PA module enters a drive state when a bias is supplied to the transistor constituting the PA module, and performs an amplification operation with a gain of more than 0. Therefore, it is only one of the PA modules M1, M4, M5 that enters a drive state.

The switch circuit SWa of the power supply system 100a adds a switch SW4 to the switch circuit SW of the power supply system 100. The switch SW3 is provided for the capacitor C3 and the PA module M4. The switch SW4 is provided for the capacitor C4 and the PA module M5.

One end of the capacitor C4 is electrically connected to the power line L3. The other end of the capacitor C4 is to be connected to a reference potential via the switch SW4. When the switch SW4 is on, the other end of the capacitor C4 is connected to the reference potential.

### Operation

The PA modules M1, M2, M3, M4, M5 amplify signals in different frequency bands. The PA module M1 amplifies, for example, UHB signals (3.5 GHz band). The PA module M2 amplifies, for example, LB signals (0.9 GHz band). The PA module M3 amplifies, for example, MB signals (1.8 GHz band). The PA module M4 amplifies, for example, UHB signals (5 GHz band). The PA module M5 amplifies, for example, HB (high band) signals (2.5 GHz band).

When the contacts a and b of the switch SW1 are connected, and a power supply voltage is supplied to the power lines L1 and L3, there may be a case where the PA modules M1, M2 are in an off-operation state, and the PA module M3 and the PA module M4 or M5 are in an on-operation state. In this case, the switch SW2 for the capacitor C2 connected to the power line L1, shared via the switch SW1 by the PA module M4 or M5 in the on state and the PA module M2 in the off state, is made off, and the switches SW3, SW4 for the capacitors C3, C4 connected to the power line L3, shared by the PA module M4 or M5 in the on state and the PA module M1 in the off state, are made off. By making off the switches SW3, SW4 for the capacitors C3, C4 connected to the power line L3, the influences of the capacitors C3, C4 can be eliminated, thereby improving the responsiveness of the PA module M1.

Further, when the PA module M1 is in an off-operation state, and the PA module M4 or the PA module M5 is in an on-operation state as described above, the switch SW5 for the capacitor C5 connected to the power line L2 is made on. The capacitor C5 is activated by making the switch SW5 on. The activation of the capacitor C5 reduces the influence of a leakage signal, which is a signal in the frequency band in which the PA module M4 or M5 operates or its harmonic signal, leaking to the PA module M3 in the on state via the power lines L2. This can ensure good isolation characteristics between the power lines L1, L3 and the power line L2.

When the contact a and the contact b of the switch SW1 are connected, the switches SW2, SW3, SW4 for the capacitor C2, connected to the power line L1, and for the capacitors C3, C4, connected to the power line L2, may be made off, and the switch SW5 for the capacitor C5, connected to the power line L2, may be made on. This can simultaneously achieve an improvement in the isolation performance between the power lines L1 and L2 and an improvement in the responsiveness.

When the contact a and the contact c of the switch SW1 are connected, and a power supply voltage is supplied to the power lines L2 and L3, there may be a case where the PA modules M1, M3 are in an off-operation state, and the PA module M2 and the PA module M4 or M5 are in an on-operation state. In this case, the switch SW5 for the capacitor C5 connected to the power line L2 is made off, and the switches SW3, SW4 for the capacitors C3, C4 connected to the power line L3 are made off. The responsiveness of the PA module M4 can be improved by thus making off the switch SW5 for the capacitor C5 connected to the power line L2 shared, via the switch SW1, by the PA module M4 or M5 in the on state and the PA module 3 in the off state. Further, the influences of the capacitors C3, C4 can be eliminated and the responsiveness of the PA module M4 can be improved by thus making off the switches SW3, SW4 for the capacitors C3, C4 connected to the power line L3 shared by the PA module M4 or M5 in the on state and the PA modules M1, M5 in the off state.

Further, when the PA module M1 is in an off-operation state, and the PA module M4 or the PA module M5 is in an on-operation state as described above, the switch SW2 for the capacitor C2 connected to the power line L1 is made on. The capacitor C2 is activated by making the switch SW2 on. The activation of the capacitor C2 reduces the influence of a leakage signal, which is a signal in the frequency band in which the PA module M4 or M5 operates or its harmonic signal, leaking to the PA module M2 via the power line L1. This can ensure good isolation characteristics between the power line L1 and the power lines L2, L3.

When the contact a and the contact c of the switch SW1 are connected, the switches SW2, SW3, SW4 for the capacitor C5, connected to the power line L2, and for the capacitors C3, C4, connected to the power line L2, may be made off, and the switch SW2 for the capacitor C2, connected to the power line L1, may be made on. This can simultaneously achieve an improvement in the isolation performance between the power lines and an improvement in the responsiveness.

Alternatively, when the contact a and the contact c of the switch SW1 are connected, the switches SW2, SW3, SW4 for the capacitor C2, C3, C4 on the power line L1 may be made off, and the switch SW5 for the capacitor C5 on the power line L2 may be made on. This can simultaneously achieve an improvement in the isolation performance between the power lines L1 and L2 and an improvement in the responsiveness.

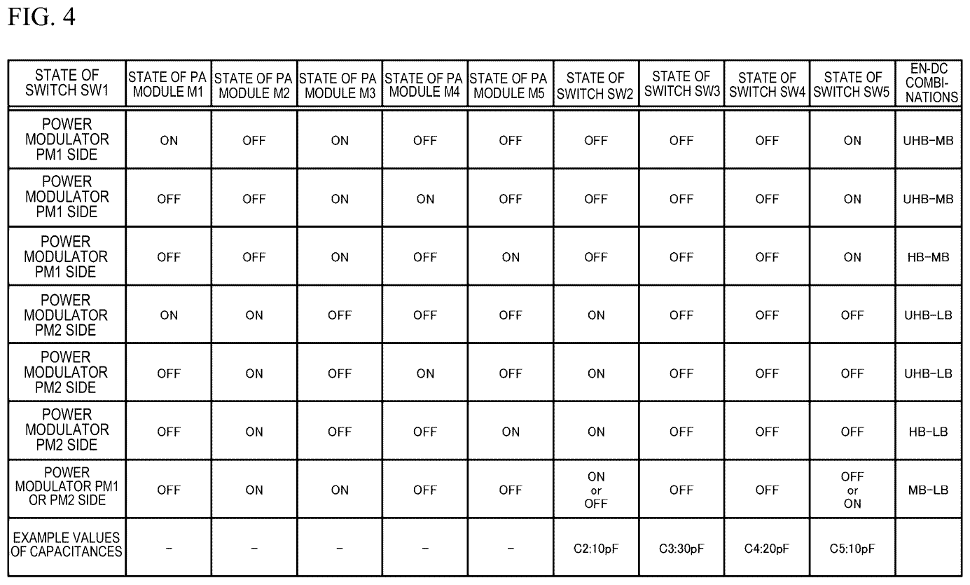

FIG. 4 shows the operating states of the PA modules in response to switching of the switch SW1 and the corresponding states of the other switches SW2, SW3, SW4, SW5. FIG. 4 also shows feasible EN-DC combinations.

In FIG. 4, when the PA module M1 is on, the PA module M2 is off, the PA module M3 is on, the PA module M4 is off, and the PA module M5 is off with the contact a of the switch SW1 connected to the power modulator PM1-side contact b, the switches SW2, SW3, and SW4 are off and the switch SW5 is on. This can achieve a combination of UHB and MB.

In FIG. 4, when the PA module M1 is off, the PA module M2 is off, the PA module M3 is on, the PA module M4 is on, and the PA module M5 is off with the contact a of the switch SW1 connected to the power modulator PM1-side contact b, the switches SW2, SW3, and SW4 are off and the switch SW5 is on. This can achieve a combination of UHB and MB.

In FIG. 4, when the PA module M1 is off, the PA module M2 is off, the PA module M3 is on, the PA module M4 is off, and the PA module M5 is on with the contact a of the switch SW1 connected to the power modulator PM1-side contact b, the switches SW2, SW3, and SW4 are off and the switch SW5 is on. This can achieve a combination of HB and MB.

In FIG. 4, when the PA module M1 is on, the PA module M2 is on, the PA module M3 is off, the PA module M4 is off, and the PA module M5 is off with the contact a of the switch SW1 connected to the power modulator PM2-side contact c, the switch SW2 is on, the switches SW3 and SW4 are off, and the switch SW5 is on. This can achieve a combination of UHB and LB.

In FIG. 4, when the PA module M1 is off, the PA module M2 is on, the PA module M3 is off, the PA module M4 is on, and the PA module M5 is off with the contact a of the switch SW1 connected to the power modulator PM2-side contact c, the switch SW2 is on, and the switches SW3, SW4, and SW5 are off. This can achieve a combination of UHB and LB.

In FIG. 4, when the PA module M1 is off, the PA module M2 is on, the PA module M3 is off, the PA module M4 is off, and the PA module M5 is on with the contact a of the switch SW1 connected to the power modulator PM2-side contact c, the switch SW2 is on, and the switches SW3, SW4, and SW5 are off. This can achieve a combination of HB and LB.

In FIG. 4, regardless of the state of connection of the contacts a, b, and c of the switch SW1, when the PA module M1 is off, the PA modules M2 and M3 are on, and the PA modules M4 and M5 are off, then the switch SW2 is on or off, the switch SW3 is off, the switch SW4 is off, and the switch SW5 is off or on. This can achieve a combination of MB and LB. The same holds true for the case where the switch SW1 is in an open state without necessarily any connection between the contacts.

FIG. 4 also shows example values of the capacitances. For example, the capacitor C2 is 10 pF, the capacitor C3 is 30 pF, the capacitor C4 is 20 pF, and the capacitor C5 is 10 pF.

### Band Combinations

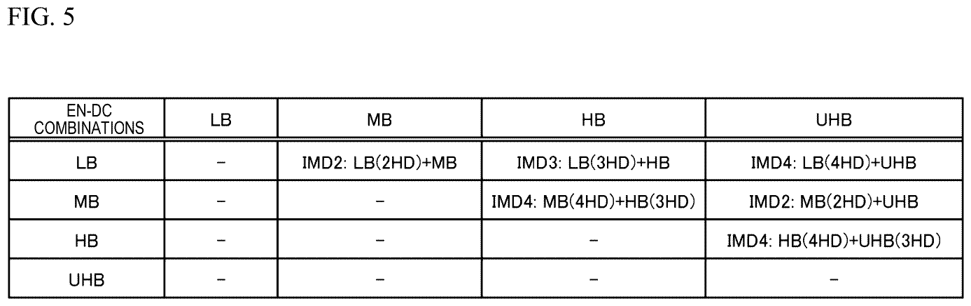

FIG. 5 is a diagram illustrating band combinations which may cause deterioration of intermodulation distortion characteristics. As shown in FIG. 5, possible band combinations are a combination of LB and MB, a combination of LB and HB, a combination of LB and UHB, a combination of MB and HB, a combination of MB and UHB, and a combination of HB and UHB. These combinations can cause intermodulation distortion (hereinafter referred to as “IMD”).

In FIG. 5, with respect to the combination of LB and MB, Mb and second-order harmonic distortion 2HD in LB can cause intermodulation distortion IMD2. With respect to the combination of LB and HB, Mb and third-order harmonic distortion 3HD in LB can cause intermodulation distortion IMD3. With respect to the combination of LB and UHB, Mb and fourth-order harmonic distortion 4HD in LB can cause intermodulation distortion IMD4. With respect to the combination of MB and HB, fourth-order harmonic distortion 4HD in MB and third-order harmonic distortion 3HD in HB can cause intermodulation distortion IMD4. With respect to the combination of MB and UHB, UHB and second-order harmonic distortion 2HD in MB can cause intermodulation distortion IMD2. With respect to the combination of HB and UHB, fourth-order harmonic distortion 4HD in HB and third-order harmonic distortion 3HD in UHB can cause intermodulation distortion IMD4.

Referring to FIG. 5, there is a concern about a high IMD level particularly for the combination of LB and MB, the combination of LB and HB, the combination of LB and UHB, and the combination of MB and UHB. The level of IMD is higher as the level of the original signal that generates the IMD is higher. The IMD level is relatively high in the combination of LB and MB, the combination of LB and HB, the combination of LB and UHB, and the combination of MB and UHB. When IMD generated upon signal transmission overlaps with a frequency band for receiving signals, desense will occur due to lowering of the reception sensitivity, resulting in a failure to meet the system specifications of a terminal. Therefore, it is suitable to reduce the level of IMD as much as possible particularly for the combination of LB and MB, the combination of LB and HB, the combination of LB and UHB, and the combination of MB and UHB.

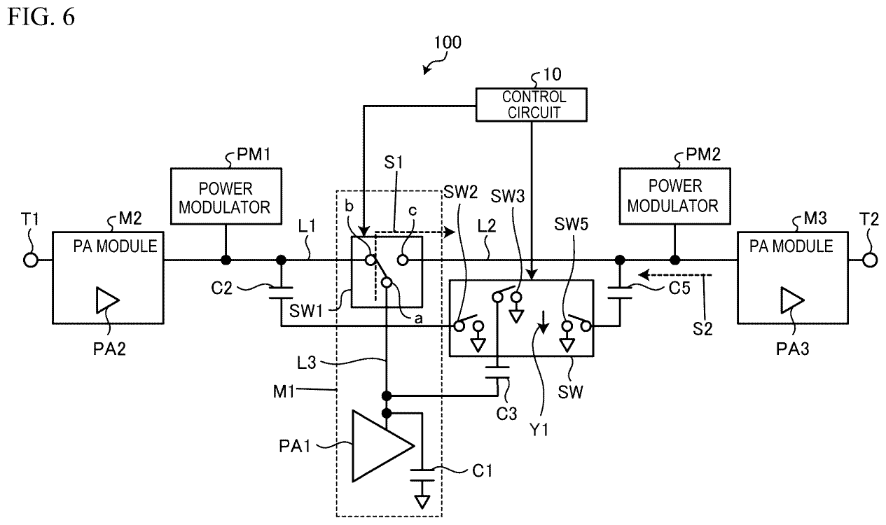

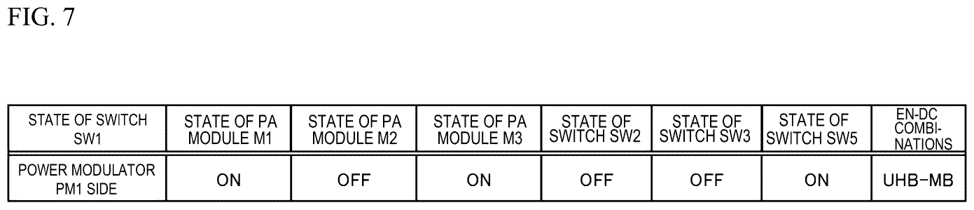

FIG. 6 is a diagram illustrating isolation characteristics between two power lines. FIG. 6 shows the flow of a leakage signal in the power supply system 100 described above with reference to FIG. 1. FIG. 7 is a diagram showing the operating states of the PA modules in the state shown in FIG. 6, and the corresponding states of the switches.

As shown in FIG. 7, when the PA module M1 is on, the PA module M2 is off, and the PA module M3 is on with the contact a of the switch SW1 connected to the power modulator PM1-side contact b, the switches SW2 and SW3 are off and the switch SW5 is on. This can achieve a combination of UHB and MB.

Returning to FIG. 6, when the contacts a and b are connected and the contacts a and c are not connected, a leakage signal S1 may leak from the power line L3 to the power line L2. For example, a fundamental wave in a UHB band may leak as a leakage signal S1. A leakage signal S2 may leak from the power line L2 to the power line L3. For example, a second harmonic in an MB band may leak as a leakage signal S2. To reduce the influence of leakage of the leakage signals S1 and S2, the switch SW5 is made on as shown by arrow Y1 to connect the capacitor C5 between the power line L2 and the reference potential. The influence of leakage can be reduced by connecting the capacitor C5 between the power line L2 and the reference potential.

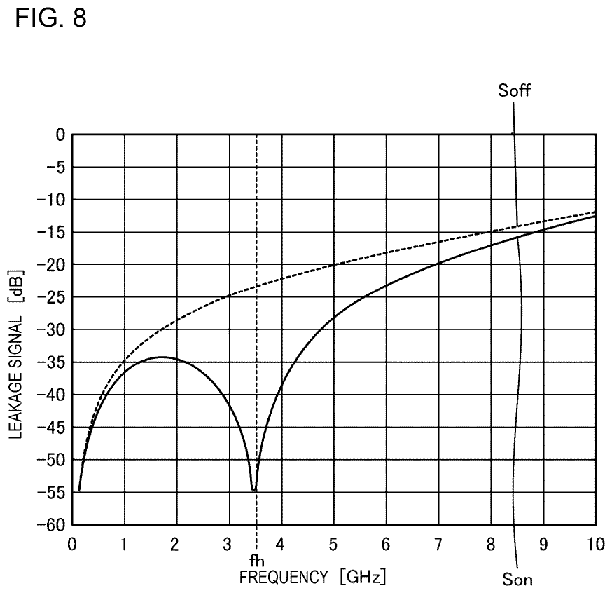

FIG. 8 is a diagram showing an example of a leakage signal in FIG. 6. In FIG. 8, the abscissa axis represents frequency (GHz), and the ordinate axis represents the level (dB) of a leakage signal. FIG. 8 shows a leakage signal Soff as observed when the switch SW5 shown in FIG. 6 is made off so that the capacitor C5 is not connected, and a leakage signal Son as observed when the switch SW5 is made on so that the capacitor C5 is connected.

As shown in FIG. 8, when the switch SW5 is made on so that the capacitor C5 is connected, there is a drop in the level of the leakage signal Son at a frequency fh near 3.5 GHZ, which corresponds to a UHB signal. In contrast, when the switch SW5 is made off so that the capacitor C5 is not connected, there is no drop in the level of the leakage signal Soff. Thus, the influence of leakage of a leakage signal can be reduced by making the switch SW5 on to connect the capacitor C5.

### Examples of Application of Power Modulators to Combinations of PM Modules

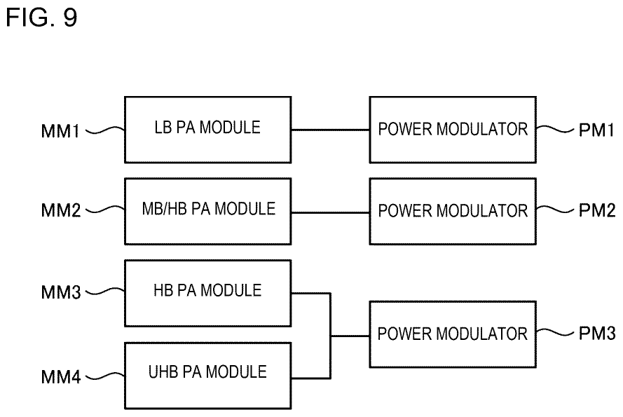

FIGS. 9 through 14 are diagrams showing examples of application of power modulators to combinations of PM modules.

FIG. 9 is a diagram showing an example of a power supply system which uses three power modulators for four PA modules. The power supply system shown in FIG. 9 includes a PA module MM1 which amplifies LB signals, a PA module MM2 which amplifies MB signals and HB signals, a PA module MM3 which amplifies HB signals, and a PA module MM4 which amplifies UHB signals. The power supply system shown in FIG. 9 also includes power modulators PM1, PM2, PM3.

The Power modulator PM1 is connected to the PA module MM1. The power modulator PM2 is connected to the PA module MM2. The power modulator PM3 is connected to the PA modules MM3 and MM4.

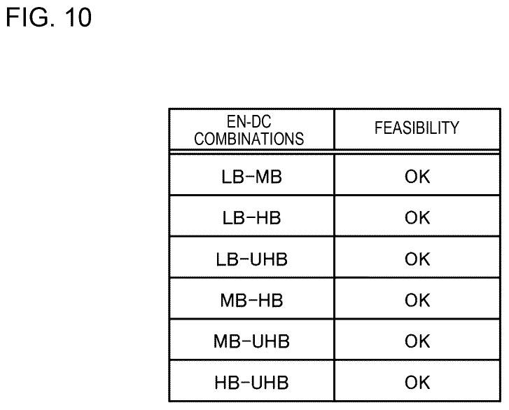

FIG. 10 is a diagram showing whether the power modulators can deal with the EN-DC combinations shown in FIG. 9. As shown in FIG. 10, when LB signals and MB signals are amplified using the PA module MM1 and the PA module MM2, power is supplied from the power modulators PM1, PM2. Thus, such an EN-DC combination can be dealt with. When LB signals and HB signals are amplified using the PA module MM1 and the PA module MM2, power is supplied from the power modulators PM1, PM2. Thus, such an EN-DC combination can be dealt with. When LB signals and UHB signals are amplified using the PA module MM1 and the PA module MM4, power is supplied from the power modulators PM1, PM3. Thus, such an EN-DC combination can be dealt with. When MB signals and HB signals are amplified using the PA module MM2 and the PA module MM3, power is supplied from the power modulators PM2, PM3. Thus, such an EN-DC combination can be dealt with. When MB signals and UHB signals are amplified using the PA module MM2 and the PA module MM4, power is supplied from the power modulators PM2, PM3. Thus, such an EN-DC combination can be dealt with. When HB signals and UHB signals are amplified using the PA module MM3 and the PA module MM4, power is supplied from the power modulators PM2, PM3. Thus, such an EN-DC combination can be dealt with. Thus, the use of the three power modulators PM1 to PM3 can deal with any of the EN-DC combinations.

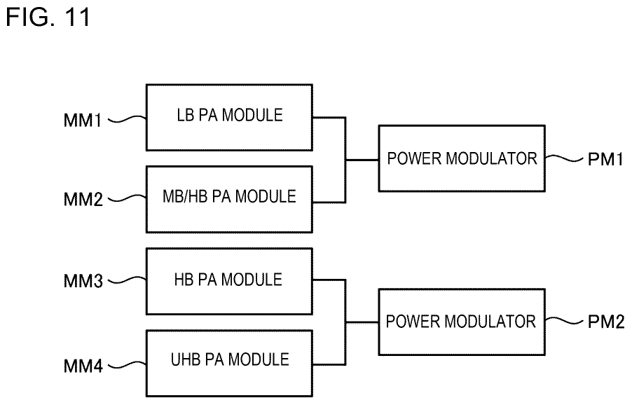

FIG. 11 is a diagram showing an example of a power supply system which uses two power modulators for four PA modules. The construction shown in FIG. 11 corresponds to the construction shown in FIG. 9 from which the power modulator PM3 is eliminated. The power modulator PM1 is connected to the PA modules MM1 and MM2. The power modulator PM2 is connected to the PA modules MM3 and MM4.

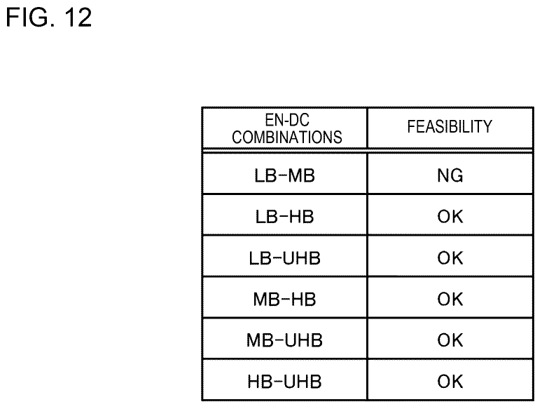

FIG. 12 is a diagram showing whether the power modulators can deal with the EN-DC combinations shown in FIG. 11. Unlike the case of FIG. 10, because of the reduced number of power modulators, the power modulators of FIG. 11 cannot deal with a certain EN-DC combination. In particular, when LB signals and MB signals are amplified, it is suitable to supply power from the power modulator PM1 to the two PA modules MM1 and MM2; such an EN-DC combination cannot be dealt with.

When LB signals and HB signals are amplified, power is supplied from the power modulator PM1 to the PA module MM1, and from the power modulator PM2 to the PA module MM3. Thus, such an EN-DC combination can be dealt with. When LB signals and UHB signals are amplified, power is supplied from the power modulator PM1 to the PA module MM1, and from the power modulator PM2 to the PA module MM4. Thus, such an EN-DC combination can be dealt with. When MB signals and HB signals are amplified, power is supplied from the power modulator PM1 to the PA module MM2, and from the power modulator PM2 to the PA module MM3. Thus, such an EN-DC combination can be dealt with. When MB signals and UHB signals are amplified, power is supplied from the power modulator PM1 to the PA module MM2, and from the power modulator PM2 to the PA module MM4. Thus, such an EN-DC combination can be dealt with. When HB signals and UHB signals are amplified, power is supplied from the power modulator PM1 to the PA module MM2, and from the power modulator PM2 to the PA module MM4. Thus, such an EN-DC combination can be dealt with.

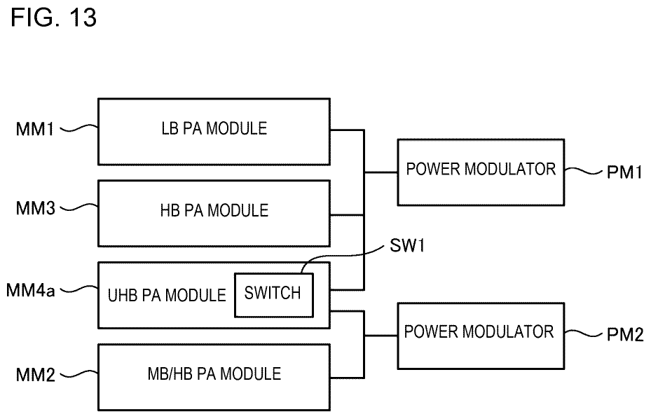

FIG. 13 is a diagram showing another example of a power supply system which uses two power modulators for four PA modules. As described above with reference to FIGS. 1 and 3, with the switch SW1 provided, the power supply system of FIG. 13 deals with EN-DC combinations with the use of two power modulators for four PA modules. In this example, the switch SW1 is provided in the PA module MM4a. By switching the state of connection of the power lines by the switch SW1, all the EN-DC combinations can be dealt with even with the use of the two power modulators for the four PA modules.

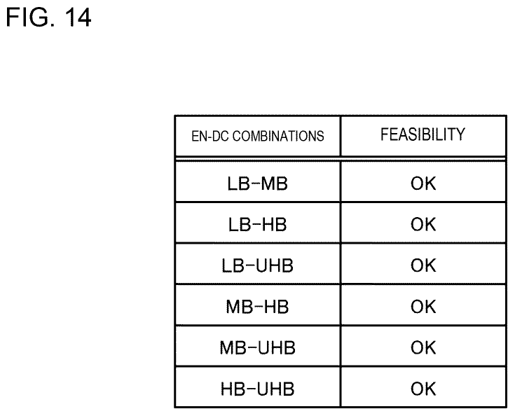

FIG. 14 is a diagram illustrating whether the power modulators can deal with the EN-DC combinations shown in FIG. 13. As shown in FIG. 14, when LB signals and MB signals are amplified, power is supplied from the power modulators PM1, PM2 to the PA modules MM1, MM2 through the setting of the switch SW1. Thus, such an EN-DC combination can be dealt with. When LB signals and HB signals are amplified, power is supplied from the power modulators PM1, PM2 to the PA modules MM1, MM2 through the setting of the switch SW1. Thus, such an EN-DC combination can be dealt with. When LB signals and UHB signals are amplified, power is supplied from the power modulator PM1 to the PA module MM1, and from the power modulator PM2 to the PA module MM4a through the setting of the switch SW1. Thus, such an EN-DC combination can be dealt with. When MB signals and HB signals are amplified, power is supplied from the power modulator PM2 to the PA module MM2, and from the power modulator PM1 to the PA module MM3 through the setting of the switch SW1. Thus, such an EN-DC combination can be dealt with. When MB signals and UHB signals are amplified, power is supplied from the power modulator PM2 to the PA module MM2, and from the power modulator PM1 to the PA module MM4a through the setting of the switch SW1. Thus, such an EN-DC combination can be dealt with. When HB signals and UHB signals are amplified, power is supplied from the power modulator PM1 to the PA module MM3, and from the power modulator PM2 to the PA module MM4a through the setting of the switch SW1. Thus, such an EN-DC combination can be dealt with. Thus, unlike the power supply system illustrated in FIGS. 11 and 12, the power supply system of this example, through switching of the switch SW1, makes it possible to deal with all the EN-DC combinations even with the use of the two power modulators PM1, PM2.

### Effect

In the second embodiment, when switching the state of connection of the power modulators PM1, PM2 to the power lines L1, L2, the switches other than the switch SW1 are operated simultaneously with switching of the switch SW1. Therefore, as in the first embodiment, it is possible to reduce the influence of a leakage signal, leaking through a power line, thereby achieving good isolation characteristics between power lines.

For a capacitor(s) which does not need to be connected, the switch is set to off so as not to connect the capacitor(s) to the reference potential. This makes it possible to prevent deterioration of the initial response performance in the operation of a PA module.

### Third Embodiment

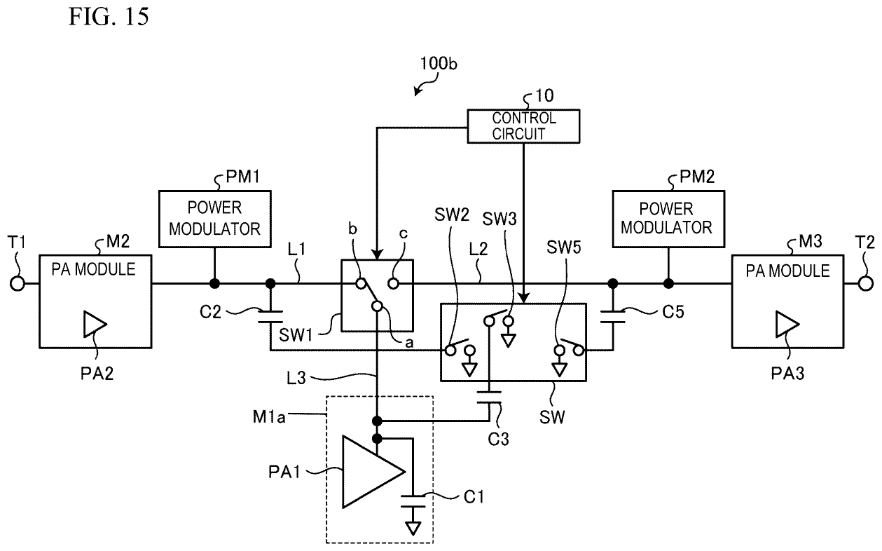

FIG. 15 is a block diagram showing a power supply system according to a third embodiment of the present disclosure. As shown in FIG. 3, unlike the power supply system 100 according to the first embodiment, the power supply system 100b according to the third embodiment has the switch SW1 provided separately from the PA module M1a. Thus, while the power supply system 100 according to the first embodiment has the switch SW1 disposed in the PA module M1, the power supply system 100b has the switch SW1 disposed outside the PA module M1a.

Despite the provision of the switch SW1 outside the PA module M1, the power supply system 100b operates the same as the power supply system 100 of the first embodiment. Thus, good isolation characteristics between the power line L1 and the power line L2 can be ensured through the setting of the switch SW1. In addition, deterioration of the initial response performance in the operation of a PA module can be prevented through the setting of the other switches SW2, SW3, SW5.

### Variations

In the above-described embodiments, the switch circuit SW or SWa may be configured as a switch array IC in which only switches are integrated. The switch circuit SW or SWa may be mounted in a PA module, or mounted on a substrate outside a PA module.

The capacitors C1 to C5, connected to the power lines L1, L2, L3, may each be an SMD component mounted in a PA module, or may be provided in the switch circuit SW or SWa. The capacitors C1 to C5 may each comprise a combination of a plurality of capacitors. The capacitors C1 to C5 may each have a fixed-value capacitance, or may each have the function of switching the capacitance value via a switch that switches between a plurality of capacitors.

What is claimed is:

1. A power supply system comprising:
a first module comprising a first power amplifier for amplifying a signal;
a first power line for supplying power to the first module;
a second power line for supplying power to the first module;
a first capacitor having a first end connected to the first power line;
a second capacitor having a first end connected to the second power line;
a first switch configured to switch between a first connection state in which the first power line is electrically connected to the first module and a second connection state in which the second power line is electrically connected to the first module;
a second switch configured to connect a second end of the second capacitor to a reference potential when the first power line is connected to the first module by the first switch and the first module is driven; and
a third switch configured to connect a second end of the first capacitor to a reference potential when the second power line is connected to the first module by the first switch and the first module is driven.

2. The power supply system according to claim 1, further comprising:
a fourth module including a fourth power amplifier for amplifying a signal; and
a third power line electrically connected to the first switch and the first module,
wherein in the first connection state, power is supplied to the first module or the fourth module via the first power line and the third power line, and
wherein in the second connection state, power is supplied to the first module or the fourth module via the second power line and the third power line.

3. The power supply system according to claim 1, further comprising a second module including a second power amplifier for amplifying a signal,
wherein the second module is connected to the first power line without a connection through the first switch, and
wherein the second switch is configured to connect the second end of the second capacitor to the reference potential when the first module and the second module are driven.

4. The power supply system according to claim 3, further comprising a third module including a third power amplifier for amplifying a signal,
wherein the third module is connected to the second power line without a connection through the first switch, and
wherein the second capacitor is connected to the second power line between the first switch and the third module.

5. The power supply system according to claim 1, further comprising a third module including a third power amplifier for amplifying a signal,
wherein the third module is connected to the second power line without a connection through the first switch, and
wherein the third switch is configured to connect the second end of the first capacitor to the reference potential when the first module and the third module are driven.

6. The power supply system according to claim 5, further comprising a second module including a second power amplifier for amplifying a signal,
wherein the second module is connected to the first power line without a connection through the first switch, and
wherein the first capacitor is connected to the first power line between the first switch and the second module.

7. The power supply system according to claim 2, wherein the frequency band of the signal amplified by the first power amplifier is different than the frequency band of the signal amplified by the fourth power amplifier.

8. The power supply system according to claim 3, wherein the frequency band of the signal amplified by the first power amplifier is different than the frequency band of the signal amplified by the second power amplifier.

9. The power supply system according to claim 4, wherein the frequency band of the signals amplified by the first power amplifier is different than the frequency band of the signal amplified by the third power amplifier.

10. The power supply system according to claim 2, further comprising:
a third capacitor having a first end connected to the third power line; and
a fourth switch configured to switch between a state in which a second end of the third capacitor is connected to a reference potential and a state in which the second end of the third capacitor is not connected to the reference potential.

11. The power supply system according to claim 10, further comprising:
a second module including a second power amplifier for amplifying a signal; and
a third module including a third power amplifier for amplifying a signal,
wherein the third capacitor is connected to a node on the third power line, the node between the first module and the fourth module, and
wherein the fourth switch is configured to connect the second end of the third capacitor to the reference potential when the second module and the third module are driven.

12. The power supply system according to claim 1, wherein the second switch and the third switch are provided in the same integrated circuit.

13. The power supply system according to claim 1, wherein the first switch is provided in the first module.

14. The power supply system according to claim 2, wherein the second switch and the third switch are provided in the same integrated circuit.

15. The power supply system according to claim 2, wherein the first switch is provided in the first module.
